(19) United States
(12) Patent Application Publication
(10) Pub. No.: US 2008/0261152 A1
(43) Pub. Date: Oct. 23, 2008

(54) METHOD OF MANUFACTURING MOTHER STAMPER AND METHOD OF MANUFACTURING STAMPER

(75) Inventor: Kenji SUGIYAMA, Odawara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 11/949,819

(22) Filed: Dec. 4, 2007

(30) Foreign Application Priority Data
Dec. 6, 2006 (JP) 2006-329234

(51) Int. Cl. G03F 7/004

(52) U.S. Cl. 430/296

(57) ABSTRACT

A method of manufacturing a mother stamper comprises: a first resist layer formation process for forming a first resist layer on a substrate; a first electron beam irradiation process for irradiating electron beam at a first pattern on the first resist layer; a first development process for developing the first resist layer to remove the non-exposed area; a second resist layer formation process for forming a second resist layer on the substrate onto which the first resist layer remains; a second electron beam irradiation process for irradiating electron beam at a second pattern on the second resist layer; a second development process for developing the second resist layer to remove the exposed area that has been exposed in the second electron beam irradiation process; and an etching process for etching the substrate to provide a grooved pattern with different depths.

### CROSS REFERENCE TO RELATED APPLICATIONS

This application claims the foreign priority benefit under Title 35, United States Code, §119(a)-(d) of Japanese Patent Application No. 2006-329234 filed on Dec. 6, 2006 in the Japan Patent Office, the disclosure of which is herein incorporated by reference in its entirety.

### FIELD OF THE INVENTION

The present invention relates to a method of manufacturing a mother stamper and a method of manufacturing a stamper.

### BACKGROUND OF THE INVENTION

In accordance with a requirement for high recording density, development have been carried out in recent years for optical information recording media with high recording density, which are to be recorded and/or read by using a laser light having a wavelength not more than 450 nm. An optical information recording medium for write-once with high recording density is manufactured by providing a recording layer containing, for example, a dye onto a resin-made disc-shaped substrate in which a pre-groove is formed for tracking of the laser light, followed by attaching a substrate for the protection of the dye recording layer. The resin substrate is manufactured by injection molding, during which a resin material is injection molded using a metal stamper having a reversely formed surface pattern as a part of a pair of molds.

The stamper is manufactured based on a grooved pattern of a mother stamper. Therefore, it is necessary to provide the mother stamper with a grooved pattern required for the resin substrate of the optical information recording medium. This grooved pattern is more finely formed as the optical information recording medium has higher recording density. Further, in accordance with diversification of information to be pre-recorded on the optical information recording medium, it is necessary to form various kinds of fine grooved patterns.

For example, Japanese Laid-open Patent Application No. 2003-22585 (see FIG. 1) discloses a technique for providing plural kinds of fine grooves. According to this known technique, a first grooved pattern is formed on a mother stamper so that a stamper is manufactured using this mother stamper, and thereafter a second grooved pattern is formed on the stamper manufactured from the mother stamper.

To be more specific, the first pattern is formed by lithography on the substrate which becomes the mother stamper. Namely, the first grooved pattern is drawn by irradiating electron beam on a resist layer formed on the substrate. This drawing process partly removes the resist layer to partly expose the substrate surface. Thereafter, the exposed area on the substrate surface is etched to provide the mother stamper having the first grooved pattern.

Next, a stamper is manufactured from the mother stamper by electroforming. The stamper has one surface on which the first grooved pattern is formed, and the second grooved pattern is formed by lithography on this surface. Therefore, it is possible to provide two different grooved patterns, for example, by forming a first groove with a predetermined depth during the etching process of the mother stamper, and by forming a second groove with a depth shallower than the first groove during the etching process of the stamper.

However, the aforementioned conventional technique has a drawback that manufacturing a stamper is time-consuming because a lithographic process is required in the manufacturing process for the mother stamper as well as in the manufacturing process for the stamper. Further, in the case where a plurality of stampers are manufactured based on the mother stamper, electroforming and lithography are repeatedly carried out at each time of manufacturing one stamper, which is very time-consuming. For this reason, it is desirable to form two different grooved patterns on the mother stamper.

In view of the foregoing drawback of the conventional technique, an object of the present invention is to provide a manufacturing method for a mother stamper, by which grooves having a different depth can be formed in the substrate constituting the mother stamper with relatively short time, and a manufacturing method for a stamper using the mother stamper to be manufactured by this method.

### SUMMARY OF THE INVENTION

According to a first aspect of the present invention, there is provided a method of manufacturing a mother stamper, which comprises: a first resist layer formation process for forming a first resist layer on a substrate; a first electron beam irradiation process for irradiating electron beam at a first pattern on the first resist layer; a first development process for developing the first resist layer so as to remove one of an area on which the electron beam has been irradiated in the first electron beam irradiation process and an area on which the electron beam has not been irradiated in the first electron beam irradiation process; a second resist layer formation process for forming a second resist layer on a surface of the substrate onto which the first resist layer is formed; a second electron beam irradiation process for irradiating electron beam at a second pattern on the second resist layer; a second development process for developing the second resist layer so as to remove one of an area on which the electron beam has been irradiated in the second electron beam irradiation process and an area on which the electron beam has not been irradiated in the second electron beam irradiation process; and an etching process for performing reactive ion etching on a surface of the substrate onto which the first resist layer and the second layer are formed so as to provide a grooved pattern with different depths on the surface of the substrate.

According to the present invention, a series of processes from the first resist layer formation process to the first development process are carried out so that the substrate surface is exposed either at the area on which the electron beam has been irradiated on the substrate in the first electron beam irradiation process or at the area on which the electron beam has not been irradiated in the first electron beam irradiation process, while the remaining area forms the first resist pattern that is formed by the remaining first resist layer. The first electron beam irradiation process is carried out such that the exposed area of the substrate at least includes an area that becomes the deepest recess portion of the finally obtained mother stamper (hereinafter referred to as a “deepest recess area”). Next, the second resist layer is formed on the substrate to entirely cover the first resist pattern (second resist layer formation process). The second electron beam irradiation process and the second development process are carried out for the second resist layer. The second electron beam irradiation process is carried out such that at least the second resist layer provided on an area associated with the deepest recess area and the second resist layer provided on an area associated with an area that becomes a shallow recess portion of the finally obtained mother stamper (hereinafter referred to as a “shallow recess area”) are removed by the second development process. Accordingly, at least three areas are formed on the substrate: an exposed area at which the surface of the substrate is exposed as a result of removing both the first resist layer and the second resist layer, an area at which the second resist layer is removed while the first resist layer substantially remains, and an area at which both the first resist layer and the second resist layer remain on the substrate. Reactive ion etching (etching process) is performed on the surface of the substrate including these three areas, so that a shallow recess portion is formed in the substrate surface at the area where the second resist layer is removed while the first resist layer substantially remains whereas a deep recess portion is formed in the substrate surface at the exposed area where the surface of the substrate is exposed as a result of removing both the first resist layer and the second resist layer. Thereafter, all the remaining resist layers on the substrate are removed by a known method to obtain a mother stamper having a grooved pattern with different depths on the surface of the substrate.

The method of this invention is particularly advantageous when compared with the conventional method, in the case where spiral-shaped grooves are formed in the surface of the substrate and the relative position between the shallow spiral and the deep spiral is important, for instance, the shallow groove and the deep groove are connected as one groove. Namely, according to the conventional manufacturing method in which the lithographic process is separately carried out twice, for example, when a part of the spiral-shaped groove (spiral pattern) extending spirally as one groove from the inner periphery to the outer periphery is formed as a shallow groove, it is very difficult to connect the shallow groove and the deep groove of the spiral pattern to form one spiral-shaped groove. On the contrary, according to the present invention, it is possible to form a spiral pattern in which a shallow groove and a deep groove are connected as one groove only by drawing one spiral pattern during one process of the second electron beam irradiation process.

In the aforementioned manufacturing method, a negative working electron beam resist may be used for the first resist layer and a positive working electron beam resist may be used for the second resist layer. According to this method, when a relatively narrow region such as to the extent of the radius of 20-21 mm is to be formed as a shallow groove, for instance, in the case of a Blu-ray Disc, etching is performed only on this relatively narrow region so that the first resist layer as a negative working resist layer remains in this narrow region. This can advantageously reduce the etching time in the first electron beam irradiation process.

In the aforementioned manufacturing method, the thickness of the first resist layer may be in the range of 5-50 nm. This is advantageous for manufacturing an optical information recording medium having a groove whose depth is approximately 60 nm, for example.

Further, in the aforementioned manufacturing method, the substrate may be a Si-containing substrate. This is advantageous because commercially available products for manufacturing semiconductor equipment, such as various kinds of resists, developers, spin coaters, and reactive ion etching devices can be used with Si-containing substrates. Therefore, it is possible to select a desired combination from a large number of options.

In the aforementioned manufacturing method, an electron beam irradiation device used in the first electron beam irradiation process and the second electron beam irradiation process may be a rotary-type electron beam exposure apparatus which performs an electron beam irradiation while rotating the disc-shaped substrate. In this instance, an offset amount between a rotation center of the Si-containing substrate in the first electron beam irradiation process and a rotation center of the Si-containing substrate in the second electron beam irradiation process is preferably not more than 50 μm. Therefore, it is possible to restrict an offset amount as little as possible between the position of the first resist layer which will remain on the Si-containing substrate and the exposure position at which electron beam is irradiated in the second electron beam irradiation process. This makes it possible to form a shallow groove and a deep groove in an appropriate position.

According to a second aspect of the present invention, there is provided a method of manufacturing a stamper, in which a mother stamper is manufactured by the aforementioned method, and electroforming is performed on the mother stamper so as to form the stamper. Based on the stamper manufactured by this method, a number of molding products can be formed by injection molding. This manufacturing method enables a stamper whose surface has a grooved pattern with different depths to be manufactured highly accurately in a short period of time without performing a further etching process as required by the conventional method.

According to the present invention, the first resist layer is provided between the substrate and the second resist layer so that grooves with a different depth can be formed in the substrate by a single etching process. Therefore, it is possible to form grooves with a different depth in the substrate in a short period of time.

### BRIEF DESCRIPTION OF THE DRAWINGS

Other objects and aspects of the present invention will become more apparent by describing in detail illustrative, non-limiting embodiments thereof with reference to the accompanying drawings, in which:

FIG. 1 is a plan view of a mother stamper used for manufacturing an optical information recording medium;

FIG. 2 is an explanatory view illustrating the depth of a groove;

FIG. 3 is a sectional view illustrating the layered structure of an optical information recording medium to be manufactured based on a mother stamper that is manufactured by the manufacturing method according to the present invention; and

FIGS. 4A to 4F are views explaining a series of manufacturing processes for manufacturing a mother stamper according to the present invention.

### DETAILED DESCRIPTION OF THE INVENTION

With reference to the accompanying drawings when necessary, one preferred embodiment of the manufacturing method for a mother stamper for an optical information recording medium (hereinafter simply referred to as a “mother stamper”) according to the present invention will be described below.

At first, a description will be given of a mother stamper manufacture by the manufacturing method according to the present invention.

A mother stamper manufactured by the manufacturing method according to the present invention is used for manufacturing fine machine parts to be used in a micro-machine, for example, for manufacturing two kinds of spiral springs with a different spring rate. However, the mother stamper is particularly advantageous for manufacturing a stamper to be used for manufacturing a substrate for an optical information recording medium. A detailed description will be given of one embodiment for manufacturing a mother stamper for an optical information recording medium.

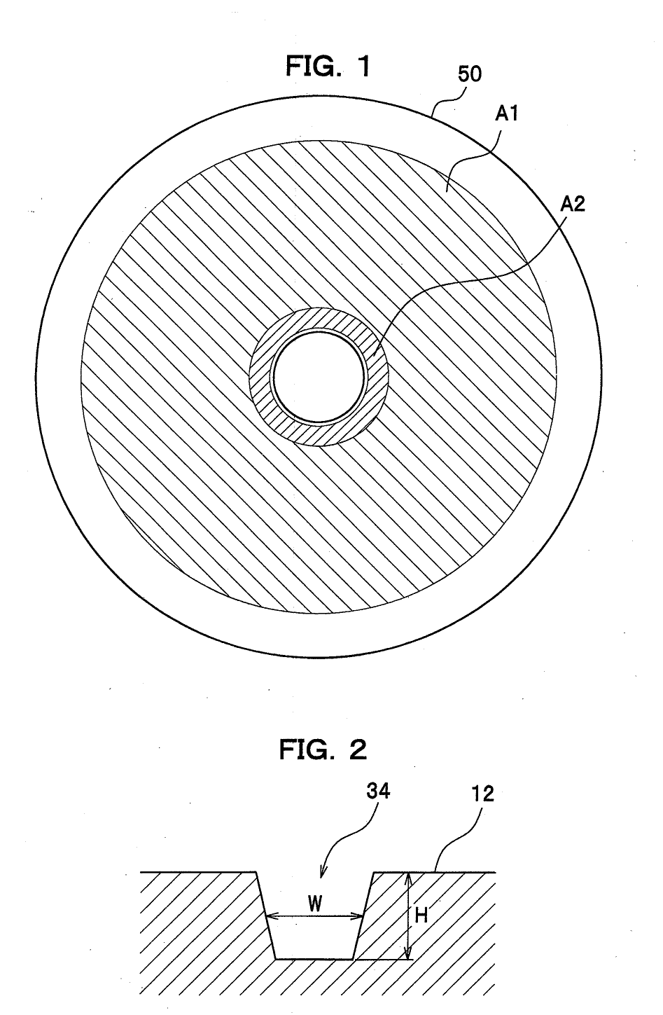

A mother stamper and a stamper for an optical information recording medium to be manufactured by the manufacturing method according to the present invention are used for manufacturing an optical information recording medium with a dye recording layer which is rerecorded and/or read with a short-wavelength laser. For example, a currently advocated Blu-ray Disc includes a management information recording area, such as BCA (Burst Cutting Area) area, at an inner periphery of the optical information recording medium, at which information such as disc information is recorded. BCA area is an area on which a BCA signal is recorded. FIG. 1 is a plan view of a mother stamper used for manufacturing this optical information recording medium, in which the hatched area indicates the BCA area. As shown in FIG. 1, a disc-shaped mother stamper 50 includes a data recording area A1 in the shape of a donut in which a spiral-shaped first pre-groove (not shown) is formed. Provided inward of the data recording area A1 is the BCA area A2. The BCA area A2 also forms a spiral-shaped second pre-groove (not shown).

In the optical information recording medium manufactured using the mother stamper 50 (namely, the optical information recording medium manufactured using a stamper that is manufactured from the mother stamper 50), the BCA signal in the form of a bar code is recorded on the dye recording layer and/or the reflective layer using a laser light. It is necessary that the pre-groove (second pre-groove) is formed in the BCA area. The depth of the second pre-groove is preferably shallower than the pre-groove (first pre-groove) formed in the data recording area A1.

As described above, more than two kinds of grooves each having a different depth include the spiral-shaped first pre-groove and the spiral-shaped second pre-groove positioned inward of the first pre-groove. Preferably, the first pre-groove and the second pre-groove satisfy a formula: A>B, where A is the depth of the first pre-groove, and B is the depth of the second pre-groove.

According to this preferred embodiment, the first pre-groove is formed as a data recording area, and the second pre-groove is formed as a management information recording area (BCA).

Preferably, the depth A of the first pre-groove is in the range of 30-50 nm, and the depth B of the second pre-groove is in the range of 5-30 nm.

Next, a description will be given of one embodiment of an optical information recording medium manufactured from the mother stamper that is manufactured by the manufacturing method according to the present invention.

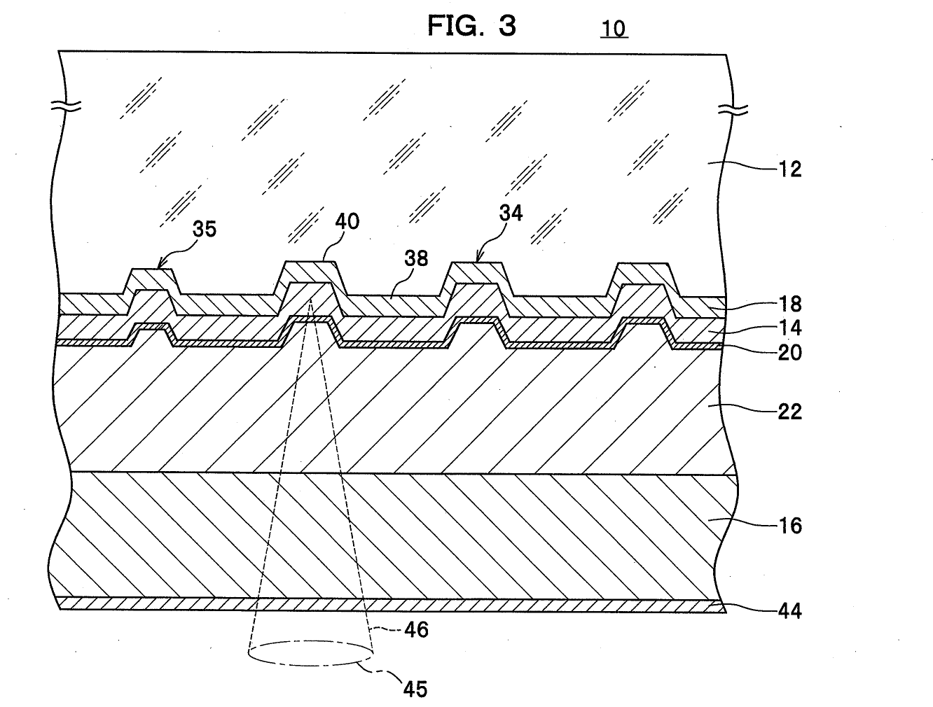

As shown in FIG. 3, the optical information recording medium 10 includes a substrate 12 with a thickness of 0.7-2 mm, a write-once dye recording layer 14, and a cover layer 16 with a thickness of 0.01-0.5 mm in this order. More specifically, a light-reflective layer 18, the write-once recording layer 14, a barrier layer 20, an adhesive layer 22, and the cover layer 16 are stacked in this order on the substrate 12.

### Substrate 12

As shown in FIG. 3, the substrate 12 for the optical information recording medium 10 includes a first pre-groove (guide groove) 34 and a second pre-groove 35. The track pitch, groove width (half width), groove depth, and Wobble amplitude of the first and the second pre-grooves 34, 35 are defined as below.

As shown in FIG. 2, the groove width indicates a value (half width) that is measured at a half of the depth H of the pre-groove and corresponding to the width W.

The first pre-groove 34 is provided with higher recording density than the pre-groove of CD-R and DVD-R media, so that the optical information recording medium 10 is suitable as a recording medium for a blue-violet laser, for example.

The second pre-groove 35 is slightly smaller in the groove width and the groove depth than the first pre-groove 34. In the case where the optical information recording medium 10 has a disc shape, the second pre-groove 34 is provided on an inner periphery side. The second pre-groove 35 is used as a BCA area, for example, for recording manufacturer data of the optical information recording medium 10, and other management information. The BCA area requires less reflectivity than the data recording area in terms of its signal characteristics and it is necessary to lower the reflectivity of the BCA area. Therefore, the groove depth of the BCA area is shallower than that of the data recording area.

The track pitch of the first pre-groove 34 is approximately 320 nm. However, it is possible to vary the track pitch when necessary in accordance with specifications of the optical information recording medium.

The groove width (half width) of the first pre-groove 34 is preferably in the range of 90-180 nm.

If the groove width of the first pre-groove 34 is less than 90 nm, the groove may not be transferred properly upon molding or the recording error rate may become higher. On the contrary, if the groove width of the first pre-groove 34 is more than 180 nm, a pit may extend upon recording, which results in cross talk or insufficient modulation degree.

The groove depth A of the first pre-groove 34 is not more than 60 nm, preferably in the range of 30-50 nm, and more preferably in the range of 35-45 nm. If the groove depth of the first pre-groove 34 is less than 5 nm, sufficient recording modulation degree can not be obtained. On the contrary, if the groove depth of the first pre-groove 34 is more than 60 nm, the reflectivity may decrease considerably.

Further, it is preferable that the inclination angle of the groove of the first pre-groove 34 is 80 degrees at most, preferably not more than 70 degrees, more preferably not more than 60 degrees, and most preferably not more than 50 degrees. On the contrary, the lowest value of the inclination angle is preferably not less than 20 degrees, more preferably not less than 30 degrees, and most preferably not less than 40 degrees.

If the inclination angle of the groove of the first pre-groove 34 is less than 20 degrees, sufficient amplitude of the tracking error signal may not be obtained. On the contrary, if the inclination angle of the groove of the first pre-groove 34 is more than 80 degrees, it becomes difficult to mold (e.g., by injection molding) the substrate 12.

The groove depth B of the second pre-groove 35 is in the range of 5-30 nm, and more preferably in the range of 8-17 nm.

The groove width (half width) of the second pre-groove 35 is arbitrarily set in the range where the groove depth B of the second pre-groove 35 lies in the aforementioned range.

The preferable inclination angle of the groove of the second pre-groove 35 is substantially the same as that of the first pre-groove 34.

Any of the conventionally known materials for a substrate for the optical information recording medium may be selected as the substrate 12 for the optical information recording medium 10 according to the present invention.

Among the materials for the substrate, thermoplastic resin such as amorphous polyolefins and polycarbonates is preferable in terms of moisture resistance, dimensional stability, and low cost. Most preferably, polycarbonates are used.

When these kinds of resin are used, the substrate 12 is manufactured by injection molding.

The thickness of the substrate 12 is in the range of 0.7-2.0 mm, preferably in the range of 0.9-1.6 mm, and more preferably 1.0-1.3 mm.

On the surface of the substrate 12 at which the light-reflective layer 18 to be described later is provided, an undercoating layer is preferably formed in order to improve planarity and adhesive force of the optical information recording medium 10.

### Write-Once Recording Layer 14

According to one preferable embodiment, the write-once recording layer 14 of the optical information recording medium 10 is formed by preparing a coating liquid into which a dye, a binder and the like are dissolved in an appropriate solvent, followed by applying the coating liquid onto the substrate or the light-reflective layer 18 to be described later and drying the thus formed coating film. The write-once recording layer 14 may be either of a single-layered or multi-layered structure. In the case of the multi-layered structure, the coating liquid application process is carried out plural times.

The application process is carried out, for example, by spray coating method, spin coating method, dip coating method, roll coating method, blade coating method, doctor roll method, screen printing method, etc.

It is preferable that the thickness of the write-once recording layer 14 to be manufactured accordingly is not more than 300 nm on the groove 38 (at the protrusions of the substrate 12), preferably not more than 250 nm, more preferably not more than 200 nm, and most preferably not more than 180 nm. On the contrary, it is preferable that the lowest value of the thickness is not less than 30 nm, preferably not less than 50 nm, more preferably not less than 70 nm, and most preferably not less than 90 nm.

It is preferable that the thickness of the write-once recording layer 14 is not more than 400 nm on the land 40 (at the recess portions of the substrate 12), more preferably not more than 300 nm, and most preferably not more than 250 nm. The lowest value of the thickness of the write-once recording layer 14 is preferably not less than 70 nm, more preferably not less than 90 nm, and most preferably not less than 110 nm.

Further, the ratio of the thickness of t1 of the write-once recording layer 14 on the groove 38 to the thickness t2 of the write-once recording layer 14 on the land 40 (i.e., t1/t2) is not less than 0.4, preferably not less than 0.5, more preferably not less than 0.6, and most preferably not less than 0.7. On the contrary, it is preferable that the highest value of t1/t2 is less than 1.0, preferably not more than 0.9, more preferably not more than 0.85, and most preferably not more than 0.8.

### Cover Layer 16

According to one preferred embodiment, the cover layer 16 of the optical information recording medium 10 is attached to the write-once recording layer 14 as described above or the barrier layer 20 to be described later by the adhesive layer 22 consisting of adhesive, pressure-sensitive adhesive, etc.

As long as it is a transparent film, any known materials may be used as the cover layer 16 for the optical information recording medium 10. However, polycarbonates, and acrylic resins such as polymethyl methacrylates; vinyl chloride resin such as polyvinyl chloride, and vinyl chloride copolymer; epoxy resin; amorphous polyolefins; polyesters; cellulose triacetate are preferable. Of these resins, use of polycarbonates or cellulose triacetate may be more preferable.

The term “transparent” indicates the permeability equal to or greater than 80% relative to the light used for recording and/or reading.

As long as the advantages of the present invention can be obtained, the cover layer 16 may contain various additives. For example, the cover layer 16 contains an UV (ultraviolet) absorbing agent for blocking light whose wavelength is 400 nm or less and/or a dye for cutting light whose wavelength is 500 nm or more.

As surface properties of the cover layer 16, it is preferable that the surface roughness is not more than 5 nm at both two-dimensional surface roughness and three-dimensional surface roughness.

Further, in terms of collecting power of the light used for recording and reading, the double refraction of the cover layer 16 is preferably 10 nm or less.

The thickness of the cover layer 16 is defined when necessary based on the wavelength of the laser light 46 irradiated for recording and reading and/or the numerical aperture (NA) of the objective lens 45. However, in the optical information recording medium 10, the thickness of the cover layer 16 is preferably in the range of 0.01-0.5 mm, and more preferably in the range of 0.05-0.12 mm.

The total thickness of the cover layer 16 and the adhesive layer 22 is preferably in the range of 0.09-0.11 nm, and more preferably in the range of 0.095-0.105 mm.

A hard coat layer 44 (protection layer) may be provided at the light incident surface of the cover layer 16 so as to prevent the light incident surface to be damaged during the manufacture of the optical information recording medium 10.

Adhesive used for the adhesive layer 22 preferably includes, for example, UV curable resin, EB curable resin, heat curable resin, etc. Of these resins, use of the UV curable resin is most preferable.

In the case where the UV curable resin is used as the adhesive, the UV curable resin may be directly applied on the surface of the barrier layer 20 by a dispenser. Alternatively, the UV curable resin may be dissolved in an appropriate solvent such as methyl ethyl ketone or ethyl acetate to prepare a coating liquid, followed by applying the coating liquid on the surface of the barrier layer 20 using the dispenser. Further, in order to prevent a skew or distortion of the optical information recording medium 10, it is preferable that the UV curable resin which forms the adhesive layer 22 has a lower shrinkage upon curing. As one example of such UV curable resin, SD-640 manufactured by DAINIPPON INK & CHEMICALS, INCORPORATED is preferable.

The adhesive is applied on a joint surface, for example, consisting of the barrier layer 20 for a predetermined amount, and thereafter the cover layer 16 is stacked thereon. The adhesive is then extended evenly by spin coating between the joint surface and the cover layer 16 and is finally cured.

It is preferable that the thickness of the adhesive layer 22 consisting of the adhesive is in the range of 0.1-100 μm, more preferably in the range of 0.5-50 μm, and most preferably in the range of 10-30 μm.

As the pressure-sensitive adhesive used for the adhesive layer 22, acrylic adhesive, rubber based adhesive, or silicon based adhesive may be used. However, in terms of transparency and durability, acrylic adhesive is preferable.

A predetermined amount of the pressure-sensitive adhesive is evenly applied on a joint surface consisting of the barrier layer 20, and thereafter the cover layer 16 is stacked prior to curing. Alternatively, a predetermined amount of the pressure-sensitive adhesive may be evenly applied on one surface of the cover layer 16 to form a coating film, and thereafter the coating film is attached to the joint surface and is finally cured.

It is also possible to attach a commercially available pressure-sensitive adhesive film with a pressure-sensitive adhesive layer on the cover layer 16.

The thickness of the adhesive layer 22 consisting of the pressure-sensitive adhesive is preferably in the range of 0.1-100 μm, more preferably in the range of 0.5-50 μm, and most preferably in the range of 10-30 μm.

### Other Layers of Optical Information Recording Medium 10

According to a preferred embodiment, the optical information recording medium 10 may include other optional layers in addition to the aforementioned layers. Such other optional layers include, for example, a label layer formed on the reverse surface of the substrate 12 (i.e., the reverse surface relative to the surface on which the write-once recording layer 14 is formed) and having a predetermined image thereon, the light-reflective layer 18 to be described later provided between the substrate 12 and the write-once recording layer 14, the barrier layer 20 to be described later provided between the write-once recording layer 14 and the cover layer 16, an interface layer provided between the light-reflective layer 18 and the write-once recording layer 14, etc. The label layer is made of UV curable resin, heat curable resin, and thermally curable resin, for example.

These layers may be of a single-layered or a multi-layered structure.

### Light-Reflective Layer 18

In order to enhance the reflectivity relative to the laser light 46 or to improve the recording/reading characteristics, the optical information recording medium 10 preferably includes the light-reflective layer 18 between the substrate 12 and the write-once recording layer 14.

The light-reflective layer 18 is made of a light-reflective material whose reflectivity to the laser light 46 is high. The light-reflective layer 18 is formed on the substrate 12 by depositing the light-reflective material by vacuum evaporation, sputtering, or ion plating.

The thickness of the light-reflective layer 18 is generally in the range of 10-300 nm, and more preferably in the range of 50-200 nm.

The reflectivity is preferably not less than 70%.

The light-reflective layer 18 is made of a material including metal such as Mg, Se, Y, Ti, Zr, Hf, V, Nb, Ta, Cr, Mo, W, Mn, Re, Fe, Co, Ni, Ru, Rh, Pd, Ir, Pt, Cu, Ag, Au, Zn, Cd, Al, Ga, In, Si, Ge, Te, Pb, Po, Sn, and Bi, semimetal, or stainless steel.

### Barrier Layer (Intermediate Layer) 20

The optical information recording medium 10 preferably forms the barrier layer 20 between the write-once recording layer 14 and the cover layer 16.

The barrier layer 20 is provided, for example, in order to improve the storage stability of the write-once recording layer 14, to improve adhesiveness between the write-once recording layer 14 and the cover layer 16, to adjust the reflectivity, or to adjust the heat conductivity.

As long as it allows permeation of the light used for recording and reading while providing the above properties, any known materials may be used as the barrier layer 20. However, in general, such materials have lower permeability for gas or moisture, and they are preferably dielectric materials.

Further, the barrier layer 20 is formed by vacuum coating such as vacuum evaporation, DC-sputtering, RF-sputtering, and ion plating. Of these methods, sputtering is more preferable, and RF sputtering is most preferable.

The thickness of the barrier layer 20 is preferably in the range of 1-200 nm, more preferably in the range of 2-100 nm, and most preferably in the range of 3-50 nm.

### Optical Information Recording Method

A recording laser light 46 such as the laser light of a semiconductor laser is irradiated on the side of the cover layer 16 via an objective lens 45 whose numerical aperture (NA) is 0.85 for example while rotating the optical information recording medium 10 at a constant linear velocity (e.g., 0.5-10 m/sec) or at a constant angular velocity. When the laser light 46 is irradiated, the write-once recording layer 14 absorbs the laser light 46 so that the temperature of the write-once recording layer 14 locally increases. This can create a physical or chemical change (e.g., formation of pits), which results in a change in optical characteristics and by which information is recorded.

As the recording laser light 46, the laser light of the semiconductor laser whose oscillation wavelength is in the range of 390-450 nm is used. A preferable light source may be a blue-violet semiconductor laser light with the oscillation wavelength in the range of 390-415 nm, or a blue-violet SHG laser light with the central oscillation wavelength of 425 nm which is obtained by reducing to a half of the wavelength of an infrared semiconductor laser light with the central oscillation wavelength of 850 nm using a light guide element. Especially, it is preferable to use the blue-violet semiconductor laser light with the oscillation wavelength in the range of 390-415 nm in terms of recording density. Upon reading the information that has been recorded as previously described, the semiconductor laser light is irradiated on the side of the substrate or on the side of the protection layer while rotating the optical information recording medium 10 at the aforementioned constant linear velocity, and the reflected light is then detected.

The laser light 46 may be a laser light in far-infrared range (normally around the wavelength of 780 nm), a visible-light laser (in the range of 630-680 nm), or a laser light whose wavelength is not more than 530 nm (blue laser light in the 405 nm range). Of these, the visible-light laser (in the range of 630-680 nm) and the laser light whose wavelength is not more than 530 nm (blue laser light in the 405 nm range) are more preferable. Most preferably, the laser light 46 is the laser light whose wavelength is not more than 530 nm (blue laser light in the 405 nm range).

Next, a description will be given of a manufacturing method for a mother stamper used for manufacturing the substrate 12 (more specifically, a stamper to be used as a mold for the substrate 12) for the optical information recording medium 10 as described above. In the following description, a rotary stage-type exposure apparatus is used as one particularly preferable embodiment.

### Manufacturing Method for Mother Stamper

Mother stamper is a mold for manufacturing a stamper. The mother stamper is manufactured by the following processes.

Negative working resist layer formation process

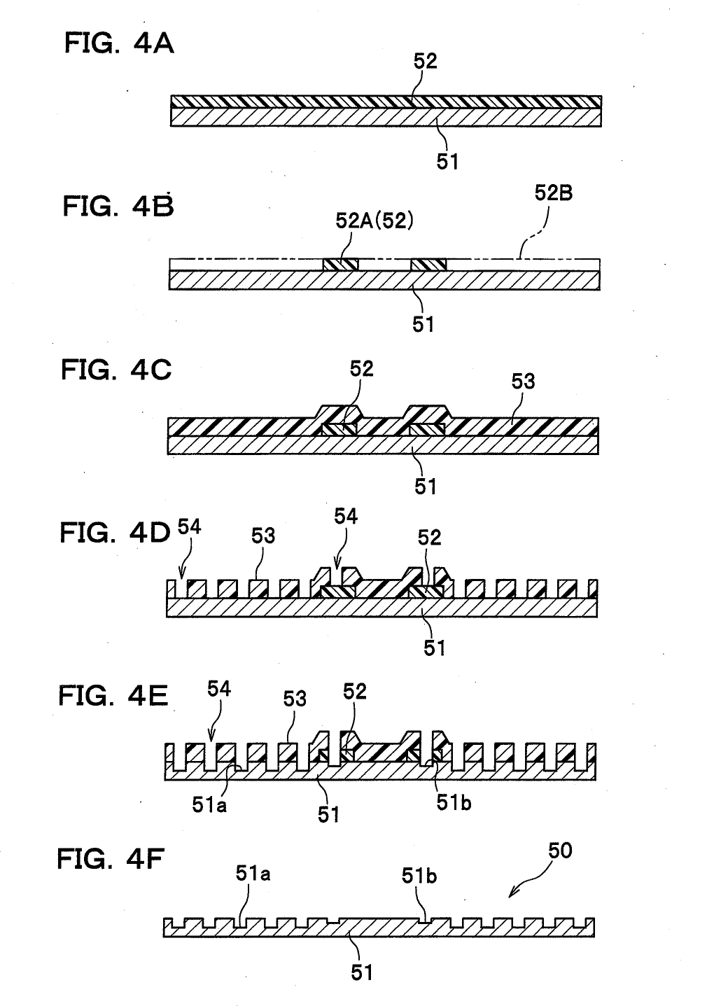

At first, a disc-shaped silicon wafer 51 (e.g., an 8 inch dummy wafer manufactured by Fujimi Fine Technology Inc.) is prepared as a silicon-containing substrate with a smoothed surface. An undercoating is applied to form a closely contact layer on the silicon wafer 51. As shown in FIG. 4A, an electron beam resist liquid is applied on the silicon wafer 51 by spin coating to form a negative working resist layer 52 which is then baked. FEN-270 manufactured by FUJIFILM Electronic Materials Co., Ltd. may be used as the electron beam resist liquid. The thickness of the negative working resist layer 52 is in the range of 5-50 nm.

### First Electron Beam Irradiation Process

As shown in FIG. 4B, electron beam is irradiated at a first pattern on the negative working resist layer 52 using an electron beam exposure apparatus equipped with a rotary stage which can highly accurately control the rotation of the silicon wafer 51. To be more specific, electron beam is irradiated on the negative working resist layer 52 in a ring-shaped range of 21-22 mm radius, so as to perform exposure. In the following description, an area of the negative working resist layer 52 where exposure has been carried out is referred to as an exposed area 52A, whereas an area where exposure has not been carried out is referred to as a non-exposed area 52B.

### First Development Process

As shown in FIG. 4B, the negative working resist layer 52 is then developed with a developer to remove the non-exposed area 52B. By this process, the ring-shaped exposed area 52A remains on the silicon wafer 51. FHD-5 manufactured by FUJIFILM Electronic Materials Co., Ltd. may be used as the developer.

Positive Working Resist Layer Formation Process

Next, an undercoating is applied to form a closely contact layer on the silicon wafer 51 and the negative working resist layer 52. As shown in FIG. 4C, an electron beam resist liquid is applied on the silicon wafer 51 and the negative working resist layer 52 by spin coating to form a positive working resist layer 53 which is then baked. FEP-171 manufactured by FUJIFILM Electronic Materials Co., Ltd. may be used as the electron beam resist liquid. The thickness of the positive working resist layer 53 is 100 nm.

### Second Electron Beam Irradiation Process

As shown in FIG. 4D, electron beam is irradiated at a second pattern on the positive working resist layer 53 using an electron beam exposure apparatus equipped with a rotary stage which can highly accurately control the rotation of the silicon wafer 51. The electron beam exposure apparatus modulates the electron beam in accordance with various signals including an address, etc. It should be noted that the offset amount between the rotation center of the silicon wafer 51 when the silicon wafer 51 is rotated by the electron beam exposure apparatus in the first electron beam irradiation process and the rotation center of the silicon wafer 51 when the silicon wafer 51 is rotated by the electron beam exposure apparatus in the second electron beam irradiation process (i.e., the rotation center of the electron beam exposure apparatus in the second electron beam irradiation process) is not more than 50 μm. More specifically, a mechanism for setting a silicon wafer 51 accurately and repeatably to the rotation center of the exposure apparatus is provided so that the offset amount can be restricted within 50 μm. As one example, a holder for fixing a silicon wafer 51 may be provided with a fine adjustment mechanism which can adjust the position of the wafer 51 in μm order. This makes it possible to fine adjust the wafer position, thereby accurately and repeatably setting the wafer relative to the holder.

The line width of the electron beam upon exposure is preferably in the range of 100-180 nm, and more preferably in the range of 120-140 nm. The address in the first pre-groove 34 or the second pre-groove 35 may be recorded such that the line formed by the exposure of the electron beam is modulated to have a wave-like pattern. In this instance, the amplitude of the wave (wobble width) is preferably in the range of 14-24 nm, and more preferably in the range of 15-17 nm. The line formed by the exposure of the electron beam may be a line of aggregated dots.

### Second Development Process

As shown in FIG. 4D, the positive working resist layer 53 is then developed with a developer to remove the exposed area. By this process, an opening 54 with a predetermined pattern is formed on the positive working resist layer 53. Any known developer may be used as long as it is reactive with the exposed positive working resist layer 53 and non-reactive with the exposed negative working resist layer 52. As one example, FHD-5 manufactured by FUJIFILM Electronic Materials Co., Ltd. may be used as the developer.

### Etching Process

As shown in FIG. 4E, an etching process is carried out via the opening 54 of the positive working resist layer 53, so as to remove the silicon wafer 51 and the negative working resist layer 52 for a predetermined amount. To be more specific, the area of the silicon wafer 51 where the negative working resist layer 52 remains is etched over the negative working resist layer 52 in a manner penetrating through the negative working resist layer 52 and reaching the silicon wafer 51. Therefore, the groove 51b formed in the area where the negative working resist layer 52 has been left on the silicon wafer 51 becomes shallower than the groove 51a formed in the area where the negative working resist layer 52 has not been left on the silicon wafer 51 to the extent of the depth corresponding to the time required for removing the negative working resist layer 52 by etching. In other words, in accordance with the thickness of the negative working resist layer 52, the shallow groove 51b that is shallower than the other groove 51a is formed on the area of the silicon wafer 51 where the negative working resist layer 52 has been left on the silicon wafer 51.

The thickness of the groove 51a is not more than 60 nm which is deeper than the groove 51b. Preferably, the thickness of the groove 51a is in the range of 30-50 nm, and more preferably in the range of 35-45 nm. Meanwhile, the thickness of the groove 51b is shallow and is in the range of 5-30 nm, and more preferably in the range of 8-17 nm. Further, the angle made by the side wall of the respective grooves 51a, 51b and the surface of the silicon wafer 51 is preferably in the range of 40-80 degrees, and more preferably in the range of 55-65 degrees.

In order to minimize undercutting (i.e., etching in the direction perpendicular to the depth direction) during the etching process, anisotropic etching is preferable. Reactive ion etching (RIE) in which an etching gas tends to travel in a straight line is used as the anisotropic etching. E620 manufactured by Panasonic Factory Solutions Co., Ltd. may be used for reactive ion etching (RIE). The etching gas may be CHF₃.

### Resist Removal Process

The resist layers 52, 53 remaining after the etching process are removed. Removal of the resist layers 52, 53 is carried out by a dry process such as ashing in which oxygen plasma is irradiated to remove organic matters. Removal of the resist layers 52, 53 may be carried out by a wet process such as using a resist stripping agent.

As shown in FIG. 4F, a mother stamper 50 is manufactured by the manufacturing method as described above.

Therefore, the mother stamper 50 manufactured according to the above manufacturing method provides two different kinds of extremely fine grooves 51a, 51b each having a different depth to each other.

A stamper is manufactured by electroforming using the mother stamper 50 that is manufactured by the above manufacturing method. Further, a substrate 12 for the optical information recording medium is manufactured from this stamper by means of injection molding.

According to the manufacturing method as described above, the following advantages can be obtained.

(1) The negative working resist layer 52 is provided between the silicon wafer 51 and the positive working resist layer 53 so that the grooves 51a, 51b with a different depth can be formed in the silicon wafer 51 by a single etching process. Therefore, it is possible to form the grooves 51a, 51b with a different depth in the silicon wafer 51 in a short period of time. Further, the mother stamper 50 is provided with grooves 51a, 51b with a different depth so that a stamper can be manufactured by electroforming without requiring a further etching process. Therefore, it is possible to reduce the manufacturing time of the stamper when compared with the conventional method which requires a further etching process such as photolithography as well as electroforming upon manufacturing the stamper.

(2) In the case where a shallow groove and a deep groove are formed in the silicon wafer 51 as one continuous groove, the manufacturing method according to this embodiment is particularly advantageous when compared with the conventional method. Namely, according to the conventional manufacturing method in which the lithographic process is separately carried out twice, for example, when a part of the spiral-shaped groove (spiral pattern) extending spirally as one groove from the inner periphery to the outer periphery is formed as a shallow groove, it is very difficult to connect the shallow groove and the deep groove of the spiral pattern to form one spiral-shaped groove. On the contrary, according to the manufacturing method as described in the preferred embodiment, it is possible to form a spiral pattern in which a shallow groove and a deep groove are connected as one groove only by drawing one spiral pattern during one process of the second electron beam irradiation process.

(3) The thickness of the negative working resist layer 52 is in the range of 5-50 nm. Therefore, it is advantageous for manufacturing an optical information recording medium whose groove depth is approximately 60 nm, for example.

(4) A rotary-type electron beam exposure apparatus is used both in the first electron beam irradiation process and the second electron beam irradiation process. For example, a spiral-shaped groove can also be formed easily.

(5) The offset amount between the rotation center of the silicon wafer 51 in the first electron beam irradiation process and the rotation center of the silicon wafer 51 in the second electron beam irradiation process is not more than 50 μm. Therefore, it is possible to restrict an offset amount as little as possible between the position of the negative working resist layer 52 which will remain on the silicon wafer 51 and the exposure position at which the electron beam is irradiated in the second electron beam irradiation process. This makes it possible to form a shallow groove and a deep groove in an appropriate position.

Although the present invention has been described with reference to specific embodiments, particularly to the method of manufacturing a substrate for an optical information recording medium, the present invention is not limited to these specific embodiments and various changes and modifications may be made without departing from the scope of the attached claims.

According to the above preferred embodiment, two different kinds of groove patterns are formed in the mother stamper 50. However, the present invention is also applicable when more than three different kinds of groove patterns are formed in the mother stamper 50. For example, prior to the positive working resist layer formation process, another negative working resist layer whose thickness is different from the negative working resist layer 52 may be formed outside the negative working resist layer 52. This makes it possible to form another groove whose depth is different from the grooves 51a, 51b. This new negative working resist layer can be formed by a similar process as described above in connection with negative working resist layer formation process.

According to the above preferred embodiment, the negative working resist layer 52 is formed as the first resist layer and the positive working resist layer 53 is formed as the second resist layer. However, the present invention is not limited to this specific arrangement, and the negative working resist layer 52 and the positive working resist layer 53 may be arranged reversely.

Further, according to the above preferred embodiment, the substrate 12 for the mother stamper 50 is the silicon wafer 51 as an Si-containing substrate. However, the present invention is not limited to this specific type, and the substrate may be made of glass or quartz.

What is claimed is:

1. A method of manufacturing a mother stamper comprising:
a first resist layer formation process for forming a first resist layer on a substrate;
a first electron beam irradiation process for irradiating electron beam at a first pattern on the first resist layer;
a first development process for developing the first resist layer so as to remove one of an area on which the electron beam has been irradiated in the first electron beam irradiation process and an area on which the electron beam has not been irradiated in the first electron beam irradiation process;
a second resist layer formation process for forming a second resist layer on a surface of the substrate onto which the first resist layer is formed;
a second electron beam irradiation process for irradiating electron beam at a second pattern on the second resist layer;
a second development process for developing the second resist layer so as to remove one of an area on which the electron beam has been irradiated in the second electron beam irradiation process and an area on which the electron beam has not been irradiated in the second electron beam irradiation process; and
an etching process for performing reactive ion etching on a surface of the substrate onto which the first resist layer and the second layer are formed so as to provide a grooved pattern with different depths on the surface of the substrate.

2. The method according to claim 1, wherein the first resist layer is a negative working resist layer and the second resist layer is a positive working resist layer.

3. The method according to claim 1, wherein the thickness of the first resist layer is in a range of 5-50 nm.

4. The method according to claim 1, wherein the substrate is a Si-containing substrate.

5. The method according to claim 4, wherein the first electron beam irradiation process and the second electron beam irradiation process are performed while rotating the Si-containing substrate, and wherein an offset amount between a rotation center of the Si-containing substrate in the first electron beam irradiation process and a rotation center of the Si-containing substrate in the second electron beam irradiation process is not more than 50 μm.

6. A method of manufacturing a stamper, wherein a mother stamper is manufactured by the method of claim 1, and electroforming is performed on the mother stamper so as to form the stamper.
